(19) United States
(12) Patent Application Publication
(10) Pub. No.: US 2026/0114250 A1
(43) Pub. Date: Apr. 23, 2026

(54) SEMICONDUCTOR DEVICE WITH MULTI-BODY BIAS USING DEEP TRENCH ISOLATION

(71) Applicant: SK keyfoundry Inc., Cheongju-si (KR)

(72) Inventors: Kwang Il KIM, Cheongju-si (KR); Yun Kyeong NAMKUNG, Cheongju-si (KR)

(21) Appl. No.: 19/072,074

(22) Filed: Mar. 6, 2025

(30) Foreign Application Priority Data
Oct. 23, 2024 (KR) 10-2024-0145783
Dec. 18, 2024 (KR) 10-2024-0189529

(51) Int. Cl. H01L 21/762; H10D 30/63; H10D 62/10; H10D 84/85

(52) U.S. Cl. CPC H10W 10/014; H10D 30/637; H10D 62/115; H10D 62/126; H10D 84/85; H10W 10/17

(57) ABSTRACT

A semiconductor device includes an N-type buried layer (NBL) formed on a substrate; an N-type deep well region (DNW) or a P-type deep-well region (DPW) on the NBL; a deep trench structure including a first deep trench isolation (first DTI) and a second DTI surrounding the NBL; a first isolation N-type well region (first ISO NW) and a second ISO NW; a first ISO N+ region and a second ISO N+ region on the first and second ISO NWs; a first NW and PW formed between the first and second ISO NWs; a first PMOS device including a first gate electrode on the first NW, a first N+ body region, first P+ source and drain regions; a first NMOS device including a second gate electrode on the first PW, a first P+ body region, first N+ source and drain regions; and a field stop PW formed between the first NW and the first ISO NW.

### CROSS-REFERENCE TO RELATED APPLICATION

This application claims the benefit under 35 U.S.C. § 119(a) of Korean Patent Application Nos. 10-2024-0145783, filed on Oct. 23, 2024, and 10-2024-0189529, filed on Dec. 18, 2024, the entire disclosures of which are incorporated herein by reference for all purposes.

### BACKGROUND

### 1. Field

The following description relates to a semiconductor device, and more particularly, to a semiconductor device with multi-body bias using deep trench isolation structure.

### 2. Description of Related Art

The statements in this section merely provide background information related to the present disclosure and do not necessarily constitute prior art.

An integrated circuit is an assembly of multiple semiconductor devices with multiple voltage potentials. There are times when it is necessary to implement multiple logic devices that apply different multi-body biases or voltages with different voltage potentials.

To manufacture a logic semiconductor device with multiple body voltages having different voltage potentials, an N-type buried layer (NBL) structure that is electrically isolated from the substrate may be used. NBL is a structure mainly used in high-voltage semiconductor devices, and an appropriate structure is required to implement it in a logic semiconductor device with multiple body voltages.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a semiconductor device includes: an N-type buried layer (NBL) formed on a semiconductor substrate; an N-type deep well region (DNW) or a P-type deep-well region (DPW) formed on the NBL; a deep trench structure including a first deep trench isolation (first DTI) and a second deep trench isolation (second DTI) surrounding the NBL; a first isolation N-type well region (first ISO NW) and a second isolation N-type well region (second ISO NW) formed on the NBL; a first ISO N-type high-concentration region (first ISO N+ region) and a second ISO N-type high-concentration region (second ISO N+ region) formed on the first ISO NW and the second ISO NW, respectively; a first N-type well region (first NW) and a first P-type well region (first PW) formed between the first ISO NW and the second ISO NW; a first PMOS device including a first gate electrode formed on the first NW, a first N-type high-concentration body region (first N+ body region), a first P-type high-concentration source region (first P+ source region), and a first P-type high-concentration drain region (first P+ drain region); a first NMOS device including a second gate electrode formed on the first PW, a first P-type high-concentration body region (first P+ body region), a first N-type high-concentration source region (first N+ source region), and a first N-type high-concentration drain region (first N+ drain region); and a field stop PW formed between the first NW and the first ISO NW, wherein the first DTI is formed in contact with the NBL and the first ISO NW and is formed deeper than the NBL, and wherein the second DTI is formed in contact with the NBL and the second ISO NW and is formed deeper than the NBL.

The semiconductor device may further include an isolation node electrically connected in common with the first ISO NW and the second ISO NW; a first node electrically connected to the first NW of the first PMOS device; and a second node electrically connected to the first PW of the first NMOS device. The isolation node, the first node, and the second node may apply an isolation voltage, a first voltage, and a second voltage, respectively, and the first node and the isolation node may be electrically connected to each other and apply the same voltage to each other. The second node may apply the second voltage that is lower than the first voltage.

A self-body bias may be electrically applied to each of the first node and the second node.

The first PMOS device and the first NMOS device may be surrounded by the first DTI, the second DTI, the first ISO NW, and the second ISO NW.

The semiconductor device may further include: a first isolation N-type deep-well region (first ISO DNW) formed between the NBL and the first ISO NW; a second isolation N-type deep-well region (second ISO DNW) formed between the NBL and the second ISO NW; a first isolation deep P-type well region (first ISO DPW) and a first isolation P-type well region (first ISO PW) formed adjacent to the first DTI and electrically connected to the substrate; and a second isolation deep P-type well region (second ISO DPW) and a second isolation P-type well region (second ISO PW) formed adjacent to the second DTI and electrically connected to the substrate.

In another general aspect, a semiconductor device includes: a first deep trench isolation (first DTI), a second deep trench isolation (second DTI), a third deep trench isolation (third DTI) and a fourth deep trench isolation (fourth DTI) formed in a semiconductor substrate, wherein the first DTI and the fourth DTI are connected to each other, and the second DTI and the third DTI are connected to each other; a first region disposed between the first DTI and the second DTI; a second region disposed between the second DTI and the third DTI; an ISO region disposed between the third DTI and the fourth DTI; a first N-type buried layer (first NBL), a second N-type buried layer (second NBL), and a third N-type buried layer (third NBL) formed in the first region, the second region, and the ISO region, respectively; a first isolation N-type deep well region (first ISO DNW) and a P-type deep well region (DPW) formed on the first NBL; an N-type deep well region (DNW) formed on the second NBL; a second isolation N-type deep well region (second ISO DNW) formed on the third NBL; a first isolation N-type well region (first ISO NW) formed on the first ISO DNW; a first N-type well region (first NW) and a first P-type well region (first PW) formed on the DPW and formed in contact with each other; a second N-type well region (second NW) and a second P-type well region (second PW) formed on the DNW and formed in contact with each other; a second isolation N-type well region (second ISO NW) formed on the second ISO DNW; a first PMOS device and a first NMOS device formed in the first region and each formed on the first NW and the first PW, respectively; and a second PMOS device and a second NMOS device formed in the second region and each formed on the second NW and the second PW, wherein the first DTI is formed in contact with the first NBL, the first ISO DNW, and the first ISO NW, and is formed deeper than the first NBL, and wherein the fourth DTI is formed in contact with the third NBL, the second ISO DNW, and the second ISO NW, and is formed deeper than the third NBL.

The first PMOS device may include a first N-type high-concentration body region (first N+ body region), a first P-type high-concentration source region (first P+ source region), and a first P+ drain region formed in the first NW. The first NMOS device may include a first P+ body region, a first N+ source region, and a first N+ drain region formed in the first PW. The second PMOS device may include a second N+ body region, a second P+ source region, and a second P+ drain region formed in the second NW, and the second NMOS device includes a second P+ body region, a second N+ source region, and a second N+ drain region formed in the second PW.

The semiconductor device may further includes: an isolation node electrically connected to the first ISO NW and the second ISO NW; a first node electrically connected to the first NW of the first PMOS device; a second node electrically connected to the first PW of the first NMOS device; a third node electrically connected to the second NW of the second PMOS device; and a fourth node electrically connected to the second PW of the second NMOS device. The isolation node, the first node, the second node, the third node, and the fourth node may apply an isolation voltage, a first voltage, a second voltage, a third voltage and a fourth voltage, respectively, such that a self-body bias is electrically applied to each of the first node, the second node, the third node and the fourth node. The isolation node and the third node may be electrically isolated from each other. The second node may apply the second voltage which is lower than the first voltage, and the fourth node may apply the fourth voltage that is lower than the third voltage.

The first PMOS device, the first NMOS device, the second PMOS device, and the second NMOS device may be disposed in that order, the DPW may be formed in contact with a bottom surface of the first NW and the first PW, and the DNW is in contact with a bottom surface of the second PW and the second NW.

A first deep trench structure may include the first DTI and the fourth DTI connected to each other, a second deep trench structure may include the second DTI and the third DTI connected to each other, and the first deep trench structure is configured to surround the second deep trench structure.

In another general aspect, a semiconductor device includes: a semiconductor substrate comprising a first region and a second region; an N-type buried layer (NBL) formed across the first region and the second region; a P-type deep well region (DPW) and an N-type deep well region (DNW) formed on the NBL and disposed adjacent to each other; a first n-type well region (first NW) and a first p-type well region (first PW) formed on the DPW in the first region and disposed in contact with each other; a second n-type well region (second NW) and a second p-type well region (second PW) formed on the DNW in the second region and disposed in contact with each other; a first PMOS device and a first NMOS device formed in the first region, wherein the first PMOS device is formed on the first NW, and the first NMOS device is formed on the first PW; a second PMOS device and a second NMOS device formed in the second region, wherein the second PMOS device is formed on the second NW, and the second NMOS device is formed on the second PW; a first isolation N-type well region (first ISO NW) formed in the first region adjacent to the first PMOS device and electrically isolated from the first NW of the first PMOS device; a second isolation N-type well region (second ISO NW) formed in the second region adjacent to the second NMOS device and electrically connected to the second NW of the second PMOS device; a first deep trench isolation (first DTI) formed adjacent to the first ISO NW and extending deeper than the NBL; and a second deep trench isolation (second DTI) formed adjacent to the second ISO NW and extending deeper than the NBL.

The semiconductor device may further include a first isolation deep N-type well region (first ISO DNW) configured to connect the NBL and the first ISO NW; and a second isolation deep N-type well region (second ISO DNW) configured to connect the NBL and the second ISO NW.

The first PMOS device may include a first N-type high concentration body region (first N+ body region) formed in the first NW, a first P-type high concentration source region (first P+ source region), and a first P+ drain region. The first NMOS device may include a first P+ body region formed in the first PW, a first N+ source region, and a first N+ drain region. The second PMOS device may include a second N+ body region formed in the second NW, a second P+ source region, and a second P+ drain region, and the second NMOS device comprises a second P+ body region formed in the second PW, a second N+ source region, and a second N+ drain region.

The semiconductor device may further include: a first node connected to the first NW of the first PMOS device; a second node connected to the first PW of the first NMOS device; a third node connected to the second NW of the second PMOS device; a fourth node connected to the second PW of the second NMOS device; a fifth node connected to the first ISO NW; and a sixth node connected to the second ISO NW. A self-body bias may be electrically applied to each of the first node, the second node, the third node and the fourth node, and the third node, the fifth node, and the sixth node are electrically coupled together and configured to receive a same voltage.

The first PMOS device, the first NMOS device, the second PMOS device, and the second NMOS device may be disposed in sequence side by side. The first PMOS device may be surrounded by the DPW, and the first NMOS device may be electrically isolated from the second PMOS device. The first NMOS device may be surrounded by the first PMOS device, the second PMOS device, and the DPW to be electrically isolated from the second NMOS device. The second PMOS device is surrounded by the first PMOS device, the second NMOS device, and the DNW to be electrically isolated from the first PMOS device. The second NMOS device may be surrounded by the second PMOS device, the DNW, and the second ISO NW to be electrically isolated from the first NMOS device. The DPW may be formed below the first PMOS device and the first NMOS device to overlap the first PMOS device and the first NMOS device, and the DNW is formed below the second PMOS device and the second NMOS device to overlap the second PMOS device and the second NMOS device.

The semiconductor device may further includes: a first shallow trench isolation (first STI) formed to overlap the first DTI; a second shallow trench isolation (second STI) formed to overlap the second DTI; a first isolation deep P-type well region (first ISO DPW) and a first isolation P-type well region (first ISO PW) formed below the first STI and electrically connected to the substrate; and a second isolation deep P-type well region (second ISO DPW) and a second isolation P-type well region (second ISO PW) formed below the second STI and electrically connected to the substrate.

Other features and aspects will be apparent from the following detailed description, the drawings, and the claims.

### BRIEF DESCRIPTION OF THE DRAWINGS

FIG. 1 illustrates a cross-sectional view of a semiconductor device having a multi-body bias according to an embodiment of the present disclosure.

FIG. 2 illustrates a cross-sectional view of a semiconductor device having a multi-body bias according to another embodiment of the present disclosure.

FIG. 3 illustrates a cross-sectional view of a semiconductor device having a multi-body bias according to another embodiment of the present disclosure.

FIG. 4 illustrates a plan view of a semiconductor device having a multi-body bias according to an embodiment of the present disclosure.

FIG. 5 illustrates a plan view of a semiconductor device having a multi-body bias according to an embodiment of the present disclosure.

FIG. 6, FIG. 7 and FIG. 8 illustrate cross-sectional views of a semiconductor device isolation for multi-body bias according to an example of the present disclosure.

FIG. 9 and FIG. 10 illustrate cross-sectional views of a semiconductor device isolation for multi-body bias according to another example of the present disclosure.

FIG. 11 and FIG. 12 illustrate plan views of a semiconductor device isolation for multi-body bias according to another example of the present disclosure.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness, noting that omissions of features and their descriptions are also not intended to be admissions of their general knowledge.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment, e.g., as to what an example or embodiment may include or implement, means that at least one example or embodiment exists where such a feature is included or implemented, while all examples are not limited thereto. The use of the term “may” herein with respect to an example or embodiment, e.g., as to what an example or embodiment may include or implement, means that at least one example or embodiment exists where such a feature is included or implemented, while all examples are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there may be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

The present disclosure is directed to providing a semiconductor device with a compact isolation structure and multi-body bias capability.

Hereinafter, the present disclosure will be described in more detail based on the embodiments illustrated in the drawings. In the various embodiments described below, the P-type may be regarded as a first conductivity type, and the N-type may be regarded as a second conductivity type.

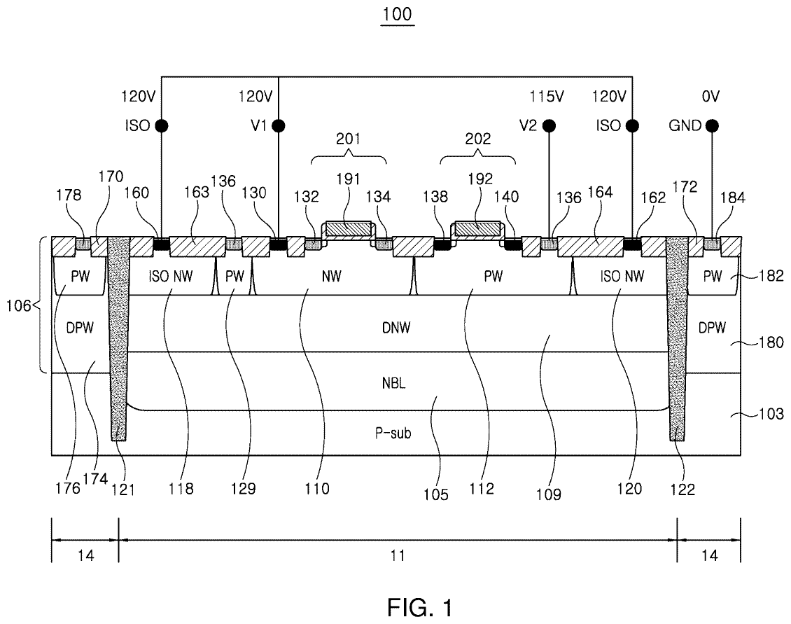

FIG. 1 illustrates a cross-sectional view of a semiconductor device having a multi-body bias according to an example of the present disclosure.

Referring to FIG. 1, a semiconductor device 100 according to an embodiment of the present disclosure may include a first region 11 and a guard ring region 14, and may include an N-type buried layer (NBL) 105 formed on a semiconductor substrate 103; an N-type deep well (DNW) 109 formed on the NBL 105; a first N-type well region (first NW) 110 and a first P-type well region (first PW) 112 formed on the DNW 109 and formed in contact with each other; and a first PMOS device 201 and a first NMOS device 202 formed on the first NW 110 and the first PW 112, respectively.

Here, the semiconductor substrate 103 may use a P-type dopant-doped substrate, abbreviated as P-sub, 103. The NBL 105 may be formed by ion-implanting N-type dopants at a high concentration into the P-sub 103, and subsequently performing a drive-in annealing process at 1000-1200° C. with mixed gases comprising N2 and O2 for curing implantation defects and growing a thermal oxide on the P-sub 103. The doping concentration of the NBL 105 may have a very high doping concentration in the range of 1E20-1E22/cm³. Then, after forming the NBL 105, an epitaxial layer 106 may be formed with a thickness of 3-10 μm to form a device layer. The DNW 109 may be formed by ion-implanting N-type dopants into the epitaxial layer 106, and subsequently performing a drive-in annealing process at 1000-1200° C. with mainly N2 gas for curing implantation defects. The concentration of the DNW 109 is 1-3 orders of magnitude lower than the dopant concentration of the NBL 105.

A semiconductor device 100 according to an embodiment of the present disclosure may further include a first isolation N-type well region (first ISO NW) 118 and a second isolation N-type well region (second ISO NW) 120 formed on the DNW 109; a first isolation N-type high concentration doping region (first ISO N+ region) 160 formed in the first ISO NW 118; and a second isolation N-type high concentration doping region (second ISO N+ region) 162 formed in the second ISO NW 120. Here, the first ISO NW 118 may be formed adjacent to the first PMOS device 201 and may be electrically connected to the first NW 110 of the first PMOS device 201. The second ISO NW 120 may be formed adjacent to the first NMOS device 202 and may be electrically connected to the first ISO NW 118 and the first NW 110.

In accordance with one embodiment of the present disclosure, a semiconductor device 100 may have a first field stop PW 129 formed between the first NW 110 and the first ISO NW 118 to increase a breakdown voltage between the first NW 110 and the first ISO NW 118. The first field stop PW 129 may be formed in contact with the DNW 109.

In a semiconductor device 100 according to one example of the present disclosure, the first PMOS device 201 formed in the first region 11 may include a first N+ body region 130, a first P+ source region 132, a first P+ drain region 134, and a first gate electrode 191 formed on the first NW 110. The first NMOS device 202 may include a first P+ body region 136, a first N+ source region 138, a first N+ drain region 140, and a second gate electrode 192 formed on the first PW 112. Here, N+ and P+ refer to regions including a high-concentration N-type dopant and a high-concentration P-type dopant, respectively.

A semiconductor device 100 according to an embodiment of the present disclosure may further include a first deep trench isolation 121 formed in contact with the first ISO NW 118 and the DNW 109 and formed deeper than the NBL 105; and a second deep trench isolation 122 formed in contact with the second ISO NW 120 and the DNW 109 and formed deeper than the NBL 105. The first DTI 121 and the second DTI 122 are connected to each other as one deep trench isolation structure.

A semiconductor device 100 according to an embodiment of the present disclosure may further include a plurality of shallow trenches. First, the plurality of shallow trenches may include a first shallow trench isolation 163 formed between a first field stop PW 129 and the first ISO NW 118; a second shallow trench isolation 164 formed between the first PW 112 and the second ISO NW 120; a third shallow trench isolation 170 formed to overlap the first DTI 121; and a fourth shallow trench isolation 172 formed to overlap the second DTI 122.

In a semiconductor device 100 according to one embodiment of the present disclosure, the guard ring region 14 may include a first guard ring region and a second guard ring region. The first and second guard ring regions may be connected together to form one guard ring region 14. The first guard ring region may comprise a first ISO DPW 174, a first ISO PW 176 and a first ISO P+ region 178 formed on the substrate 103. The second guard ring region may comprise a second ISO DPW 180, a second ISO PW 182, and a second ISO P+ region 184 formed on the substrate 103.

According to an embodiment of the present disclosure, a semiconductor device 100 may comprise an isolation node ISO to apply an isolation voltage. The isolation node ISO may be electrically connected to the first ISO NW 118 and the second ISO NW 120. A first node V1 and a second node V2 may be electrically connected to the first NW 110 and the first PW 112, respectively, to apply a first voltage and a second voltage. Here, the ISO, V1, and V2 may include a metal contact plug, a metal wiring, or a metal pad configured to apply a voltage.

The maximum isolation voltage that may be applied to the semiconductor device 100 according to one embodiment of the present disclosure may be about 120 V. This is because a high-concentration NBL 105 and a deep trench structure 121, 122 are formed in the semiconductor device 100 between the P-sub 103 and the isolation node ISO.

Therefore, the semiconductor device 100 according to one example of the present disclosure may include the isolation node ISO commonly electrically connected to the first ISO NW 118 and the second ISO NW 120; and the first node V1 electrically connected to the first NW 110 of the first PMOS device 201. Here, the first ISO NW 118, the second ISO NW 120, the first NW 110, and the DNW region 109 are electrically connected to each other. Therefore, the first ISO NW 118, the second ISO NW 120, the first NW 110, and the DNW region 109 are applied with the same isolation voltage, for example 120V.

In addition, the first ISO NW 118, the second ISO NW 120, and the first NW 110 are electrically separated from the substrate 103 by the NBL 105 and the DNW 109. Here, the isolation node ISO and the first node V1 are electrically connected to each other with the first ISO NW 118, the second ISO NW 120, and the first NW 110. This allows the isolation node ISO and the first node V1 to have different voltages applied to them than the substrate 103. For example, when a voltage of 0 V is applied to a ground node GND in the ISO PW 182 electrically connected to the substrate 103, the isolation node ISO and the first node V1 may be applied with up to 120 V. A possible reason is that since a high dopant concentration of the NBL 105 is formed compared to the substrate 103, the isolation node ISO and the first node V1 do not punch through with the substrate 103 due to the high dopant concentration of the NBL 105, even when the maximum 120 V is applied.

The first NMOS device 202 may include a second node V2 electrically connected to the first PW 112. The first PW 112 of the first NMOS device 202 is completely surrounded by N-type well regions 109, 110, 120. Therefore, the first PW 112 of the first NMOS device 202 is completely electrically isolated from the substrate (P-sub) 103, and a voltage different from the substrate 103 may be applied to the first PW 112 of the first NMOS device 202. For example, when a voltage of 0 V is applied to the substrate 103, a voltage of up to 115 V, which is much higher than that, may be applied to the first PW 112 of the first NMOS device 202.

The first node V1 and the second node V2, which are electrically connected to the body regions of the first PMOS 201 and the first NMOS 202, respectively, may apply different bias voltages. For example, when 120 V is applied to V1, V2 may have a lower voltage of 115 V applied to it. A self-body bias may be applied electrically to each of the first node V1 and the second node V2. Applying the self-body bias may effectively create a voltage difference between the first node V1 and the second node V2, which can dynamically adjust the threshold voltages of the first PMOS and NMOS transistor to influence their switching behavior and performance to optimize power consumption and circuit characteristics.

Here, it is preferable to apply a higher voltage to the first NW 110 than to the first PW 112. This is because when a higher voltage is applied to the first PW 112, a PN diode operation occurs between the first PW 112 and the first NW 110. When the PN diode operation occurs, a leakage current may easily occur from the first PW 112 to the first NW 110. To prevent such PN diode operation, it is preferable to apply a higher voltage to the first NW 110 among the first PW 112 and the first NW 110 that are in contact with each other.

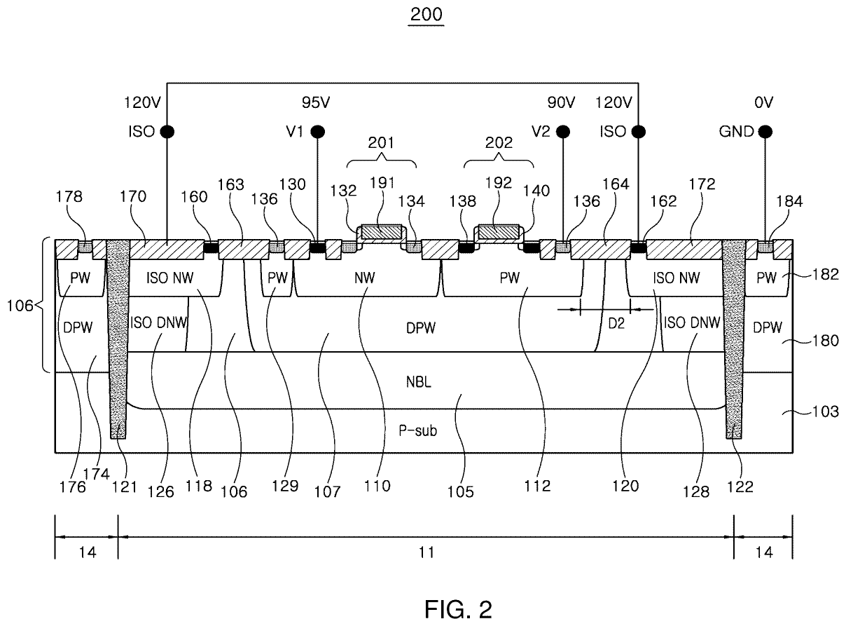

FIG. 2 illustrates a cross-sectional view of a semiconductor device having a multi-body bias according to another embodiment of the present disclosure.

Referring now to FIG. 2, a semiconductor device 200 according to an embodiment of the present disclosure is shown similarly to FIG. 1. However, it differs in that a DPW 107 is formed on an NBL 105. The DPW 107 may be formed by ion-implanting a P-type dopant after forming an epitaxial layer 106 and performing a drive-in annealing process at 1000-1200° C. The dopant concentration of the DPW 107 is much lower than the dopant concentration of the NBL 105 by 1-3 orders of magnitude. The DPW 107 completely surrounds the first NW 110, the first PW 112, and the field stop PW 129. Thus, the first NW 110, the first PW 112, and the field stop PW 129 may be electrically separated from the first ISO NW 118 and the second ISO NW 120.

According to an embodiment of the present disclosure, a semiconductor device 200 may first electrically connect an isolation node ISO on a first ISO NW 118 and a second ISO NW 120 to apply an isolation voltage. Then, a first node V1 and a second node V2 may be electrically connected on a first NW 110 and a first PW 112, respectively, to apply a first voltage and a second voltage. Here, the ISO, V1, and V2 may include a metal contact plug, a metal wiring, or a metal pad configured to apply a voltage.

The maximum isolation voltage that may be applied to the semiconductor device 200 according to one embodiment of the present disclosure may be about 120 V. This is because a high-concentration NBL 105 and a deep trench structure 121, 122 are formed in the semiconductor device 200 between the P-sub 103 and the ISO.

First, a first voltage may be applied to the first N+ body region 130, and a voltage different from the isolation voltage may be applied. This is because the first PMOS 201 structure to which the first voltage is applied is completely surrounded by P-type well regions 107, 129, 112. That is, V1 and ISO are electrically separated. The first NW 110 electrically connected to V1 by the P-type well regions 107, 129, 112 and the ISO NW 118 electrically connected to ISO are insulated from each other. Therefore, different voltages may be applied to V1 and ISO.

For example, when 120 V is applied to ISO, 95 V, which is lower than that, may be applied to V1. Here, the voltage difference between the isolation node ISO and the first node V1 may be up to 25 V. Also, the voltage difference between the first voltage and the second voltage may be up to 5 V. The breakdown voltage value may vary depending on the distance and concentration between well regions, and the maximum applied voltage difference may be set depending on the value.

As mentioned above, it is preferable to apply a higher voltage to the first NW 110 than to the first PW 112. For example, when 95 V is applied to V1, 90 V, which is lower than that, may be applied to V2. Here, it is preferable to apply a higher voltage to the first NW 110 than to the first PW 112. This is because when a higher voltage is applied to the first PW 112, a PN diode operation occurs between the first PW 112 and the first NW 110. When the PN diode operation occurs, a leakage current may easily occur from the first PW 112 to the first NW 110. To prevent such PN diode operation, it is preferable to apply a higher voltage to the first NW 110 among the first PW 112 and the first NW 110 that are in contact with each other.

A self-body bias may be electrically applied to each of the first node V1 and the second node V2. By applying the self-body bias, a voltage difference can be effectively created between the first node V1 and the second node V2, which allows the threshold voltages of the first PMOS and NMOS transistors 201 and 202 to be dynamically adjusted to affect switching behavior and performance to optimize power consumption and circuit characteristics. The remainder of the description of FIG. 2 is similar to FIG. 1 and is therefore omitted.

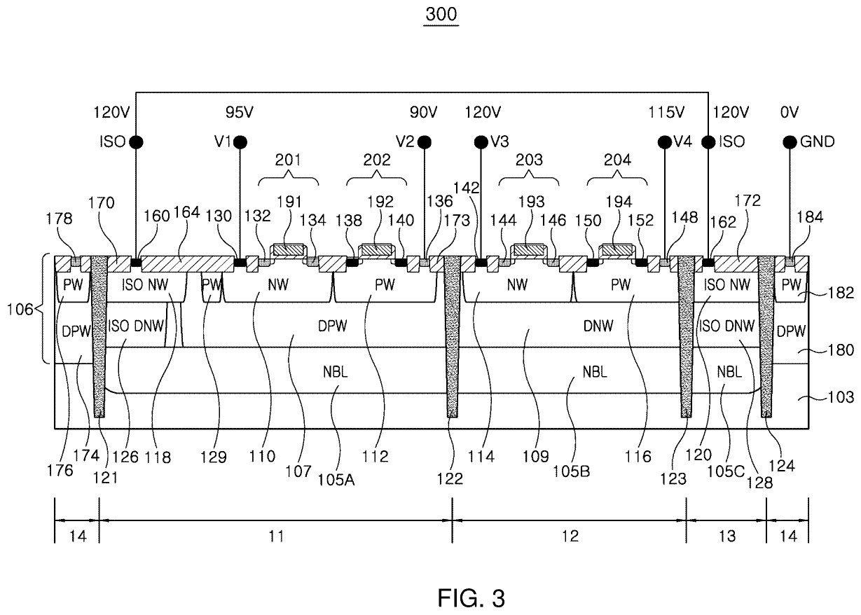

FIG. 3 illustrates a cross-sectional view of a semiconductor device having a multi-body bias according to another embodiment of the present disclosure.

Referring to FIG. 3, a semiconductor device 300 according to an example of the present disclosure includes a semiconductor substrate 103 including a first region 11, a second region 12, an isolation region 13, and a guard ring region 14. A first deep trench isolation (first DTI) 121, a second deep trench isolation (second DTI) 122, a third deep trench isolation (third DTI) 123, and a fourth deep trench isolation (fourth DTI) 124 are formed between each region of the first region 11, the second region 12, the isolation region 13, and the guard ring region 14. In addition, each region may be electrically isolated by the deep trench isolations 121-124.

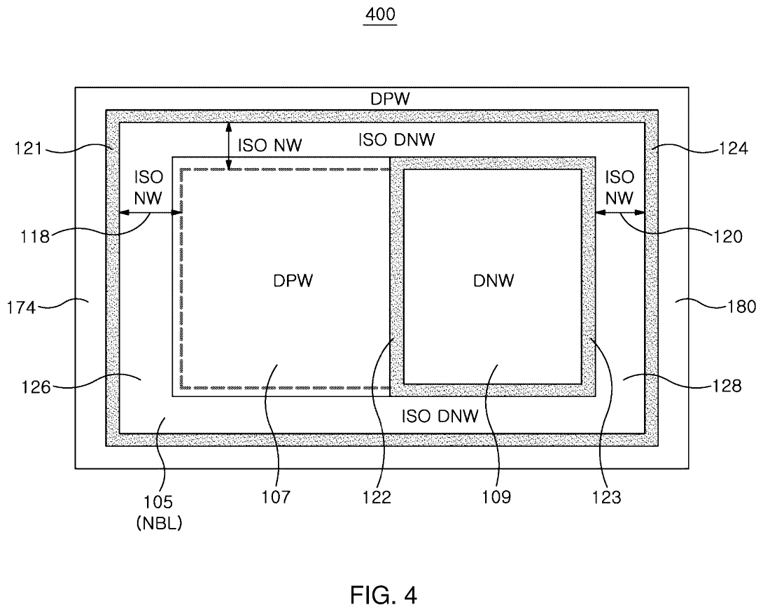

Here, the first DTI 121 and the fourth DTI 124 are connected to each other as a single deep trench structure (see FIG. 4). Therefore, the first DTI 121 and the fourth DTI 124 may be viewed as a first deep trench structure that is connected to each other.

In addition, the second DTI 122 and the third DTI 123 are also connected to each other as one deep trench structure which may be viewed as a second deep trench structure (see FIG. 4). Therefore, the second DTI 122 and the third DTI 123 may be viewed as a second deep trench structure that is connected to each other. The second deep trench structure is surrounded by the first DTI structure. The device within the second deep trench structure may be electrically isolated from the device within the first DTI structure.

A semiconductor device 300 according to one embodiment of the present disclosure may include a first NBL 105A, a second NBL 105B, and a third NBL 105C formed in the first region 11, the second region 12, and the isolation region 13, respectively. The first NBL 105A, the second NBL 105B, and the third NBL 105C are originally formed as one NBL 105, and then separated by a first DTI 121, a second DTI 122, a third DTI 123, and a fourth DTI 124 structure.

The first region 11 may include a DPW 107 formed on the first NBL 105A; a first isolation N-type deep well region (first ISO DNW) 126; a first NW 110 and a first PW 112 formed on the DPW 107 and in contact with each other; and a first PMOS device 201 and a first NMOS device 202 formed on the first NW 110 and the first PW 112, respectively. In addition, a first ISO NW 118 may be formed on the first ISO DNW 126. A first ISO N+ region 160 may be formed in the first ISO NW 118. A field stop PW 129 may be further formed between the first NW 110 and the first ISO NW 118 to increase a breakdown voltage. The field stop PW 129 may be formed in the DPW 107. Here, the substrate 103 may use a P-type substrate doped with a P-type dopant. The first ISO DNW 126 may be formed by ion-implanting an N-type dopant into the epitaxial layer 106 and performing a drive-in annealing process at 1000-1200° C. The DNW 109 and the first ISO DNW 126 may be formed in the same step under the same conditions in order to simplify the process and save costs.

The first PMOS device 201 of the first region 11 may include a first N+ body region 130, a first P+ source region 132, a first P+ drain region 134, and a first gate electrode 191 formed on the first NW 110. The first NMOS device 202 may include a first P+ body region 136, a first N+ source region 138, a first N+ drain region 140, and a second gate electrode 192 formed on the first PW 112.

The second region 12 may include a DNW 109 formed on the second NBL 105B; a second NW 114 and a second PW 116 formed on the DNW 109 and formed in contact with each other; a second PMOS device 203 and a second NMOS device 204 formed on the second NW 114 and the second PW 116, respectively, which are formed on the DNW 109.

The second PMOS device 203 of the second region 12 may include a second N+ body region 142, a second P+ source region 144, a second P+ drain region 146, and a third gate electrode 193 formed on the second NW 114. The second NMOS device 204 may include a second P+ body region 148, a second N+ source region 150, a second N+ drain region 152, and a fourth gate electrode 194 formed on the second PW 116.

The isolation region 13 may include a second isolation N-type deep well region (second ISO DNW) 128 formed on the third NBL 105C; a second ISO NW 120; and a second ISO N+region 162.

Here, each of the lower surface (or bottom surface) of the DPW 107 and the first ISO DNW 126 is in contact with an upper surface (or top surface) of the first NBL 105A. Each lower surface (or bottom surface) of the DNW 109 is in contact with an upper surface (or top surface) of the second NBL 105B. A lower surface (or bottom surface) of the second ISO DNW 128 is in contact with an upper surface (or top surface) of the third NBL 105C.

A semiconductor device 300 according to an embodiment of the present disclosure may further include a first node V1 connected to the first NW 110 of the first PMOS device 201 to apply a first voltage; and a second node V2 connected to the first PW 112 of the first NMOS device 202 to apply a second voltage. In addition, the first node V1 and the second node V2 may apply electrically different body biases, respectively.

The first node V1 and the second node V2 are connected to the first NW 110 and the first PW 112, respectively. The first node V1 and the second node V2 are respectively connected to well regions of different conductivity types.

In addition, the first NW 110 and the first PW 112, which are respectively connected to the first node V1 and the second node V2, are electrically separated from the substrate 103 by the first NBL 105A and the DPW 107. Therefore, the first node V1 and the second node V2 may apply different voltages than the substrate.

A semiconductor device 300 according to one embodiment of the present disclosure further includes a third node V3 connected to the second NW 114 of the second PMOS device 203; and a fourth node V4 connected to the second PW 116 of the second NMOS device 204, wherein the third node V3 and the fourth node V4 may apply electrically different body biases, respectively.

Here, the first node V1 and the third node V3, which are electrically connected to the first NW 110 and the second NW 114, respectively, may apply different bias voltages. This is because the first NW 110 connected to the first node V1 is surrounded by a P-type well region formed by a DPW 107, a first PW 112, and a field stop PW 129. This is because the P-type well region formed by the DPW 107, the first PW 112, and the field stop PW 129 prevents an electrical short between the first NW 110 and the second NW 114.

Since the second PMOS device 203 connected to the third node V3 is surrounded by the second and third deep trench isolation structures 122, 123, it may be completely electrically isolated from the first PMOS device 201 and the first NMOS device 202. The size of a chip using four devices may be reduced by the second and third deep trench isolation structures 122, 123. This is because, in the conventional method, a very wide junction structure was used to prevent an electrical short between the first NW 110 and the second NW 114. Instead of a very wide junction isolation structure, the second and third deep trench isolation structures 122, 123 with a small area may be used to easily electrically isolate the devices from each other.

Similarly, the second node V2 and the fourth node V4 connected to the first PW 112 and the second PW 116 respectively may apply different biases. This is because the second NMOS device 204 connected to the fourth node V4 is surrounded by the second and third deep trench isolation structures 122, 123.

A semiconductor device 300 according to one embodiment of the present disclosure further includes an isolation node ISO electrically connected to the first ISO NW 118 and the second ISO NW 120. The third node V3 and the isolation node ISO are electrically separated from each other. Different voltages may be respectively applied to the third node V3 and the isolation node ISO. The reason why the third node V3 and the isolation node ISO are electrically separated from each other is because the third node V3 is surrounded by second and third deep trench isolation structures 122, 123.

In a semiconductor device 300 according to one embodiment of the present disclosure, the first PMOS device 201, the first NMOS device 202, the second PMOS device 203, and the second NMOS device 204 are formed in a parallel manner in that order, and by a structure of a first deep trench isolation 121, a second deep trench isolation 122, a third deep trench isolation 123, and a fourth deep trench isolation 124, the first PMOS device 201 and the second PMOS device 203 may be electrically isolated, and the first NMOS device 202 and the second NMOS device 204 may be electrically isolated.

In a semiconductor device 300 according to one embodiment of the present disclosure, the DPW 107 may be formed in contact with lower surfaces of the first NW 110 and the first PW 112, and the DNW 109 may be formed in contact with lower surfaces of the second NW 114 and the second PW 116. The first PMOS device 201 is surrounded by the DPW 107 and the first PW 112. The first NMOS device 202 is surrounded by the DPW 107, the first NW 110, and the second DTI 122. The second PMOS device 203 is surrounded by the second DTI 122, the DNW 109, and the second PW 116. The second NMOS 204 is surrounded by the DNW 109, the second NW 114, and the third DTI 123. The remaining regions of FIG. 3 are similar to FIG. 1 or FIG. 2 and thus will be omitted.

Referring to FIG. 3, different multi-voltages may be applied to each well region in a semiconductor device 300 according to another embodiment of the present disclosure. First, in order to apply an isolation voltage, ISO may be electrically connected to a first ISO NW 118 and a second ISO NW 120. In order to apply a first voltage, a second voltage, a third voltage, and a fourth voltage, V1, V2, V3, and V4 may be connected to the first NW 110, the first PW 112, the second NW 114, and the second PW 116, respectively. Here, ISO, V1, V2, V3, and V4 may include a metal contact plug, a metal wiring, or a metal pad configured to apply a voltage.

The maximum isolation voltage that may be applied to the semiconductor device 300 according to one embodiment of the present disclosure may be about 120 V. This is because a high-concentration NBL 105 and a deep trench structure 121, 122, 123, 124 are formed in the semiconductor device 300 between the P-sub 103 and the ISO.

Since the difference in breakdown voltage between the NWs 110, 114 and the PWs 112, 116 is within 5 V, it is possible to apply a higher voltage to the NWs 110, 114 than to the PWs 112, 116 within 5 V. For example, when V1=95 V is applied to the first NW 110, V2=90 to 95 V may be applied to the first PW 112. Also, when V3=120 V is applied to the second NW 114, V4=110 to 115 V may be applied to the second PW 116. In this way, V1 to V4 may apply different body biases. A self-body bias may be electrically applied to each of the first node V1, the second node V2, the third node V3 and the four node V4. Applying the self-body bias may effectively create a voltage difference from V1 to V4, which allows for dynamic adjustment of each threshold voltage of the first and second PMOS and NMOS transistor (201 to 204) to influence switching behavior and performance to optimize power consumption and circuit characteristics.

FIG. 4 illustrates a plan view of a semiconductor device having a multi-body bias according to an embodiment of the present disclosure.

Referring to FIG. 4, the first and fourth deep trench isolations 121, 124 may be formed to surround the ISO DNWs 126, 128 in a semiconductor device 400. The second and third deep trench isolation 122, 123 structures surrounding the DNW 109 on the semiconductor substrate may be seen in the semiconductor device 400. The DPW 107 may be formed to be surrounded by the first and fourth deep trench isolations 121, 124.

The first and second ISO DNWs 126, 128 may be formed to surround the DPW 107, the DNW 109, and the second and third deep trench isolations 122, 123. The first and second ISO DNWs 126, 128 may be connected to each other to form one ISO DNW 126, 128.

The first and second ISO NWs 118, 120 may be formed to overlap the ISO DNW 126, 128. The first and second ISO NWs 118, 120 may be connected to each other to form one ISO NW 118, 120. The ISO NW 118, 120 may be formed to overlap the DPW 107 and the DNW 109.

As seen in the plan view, the ISO DNWs 126, 128 and the ISO NWs 118, 120 are electrically connected to the NBL 105.

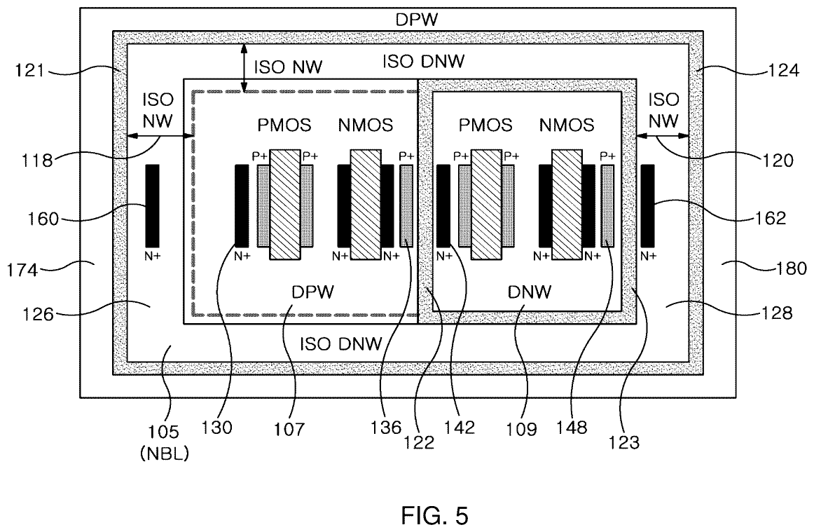

FIG. 5 illustrates a plan view of a semiconductor device having a multi-body bias according to an embodiment of the present disclosure.

Referring to FIG. 5, a first deep trench structure comprising the first and fourth deep trench isolations 121, 124 may be formed in a semiconductor device 500. A second deep trench structure comprising the second and third deep trench isolations 122, 123 may be formed in the semiconductor device 500. Therefore, the first PMOS 201 and the first NMOS 202 are surrounded by the first deep trench structure 121, 124. The second PMOS 203 and the second NMOS 204 are surrounded by the second deep trench structure 122, 123. The first PMOS 201 and the first NMOS 202 may be formed on the DPW 107. It may also be seen that the second PMOS 203 and the second NMOS 204 are formed on the DNW 109.

An N+ region 130 and a P+ region 136 may be formed respectively on the DPW 107 to apply a first voltage and a second voltage. As explained above, the first voltage and the second voltage are different voltages.

Likewise, the N+ region 142 and the P+ region 148 may be formed respectively on the DNW 109 to apply the V3 voltage and the V4 voltage, respectively. As described above, the V3 voltage and the V4 voltage are different voltages. In addition, the V1 to V4 voltages may all apply different voltages.

The DPW 107 may be formed to overlap with the first PMOS 201 and the first NMOS 202 in the semiconductor device 500. Also, the DNW 109 may be formed to overlap with the second PMOS 203 and the second NMOS 204.

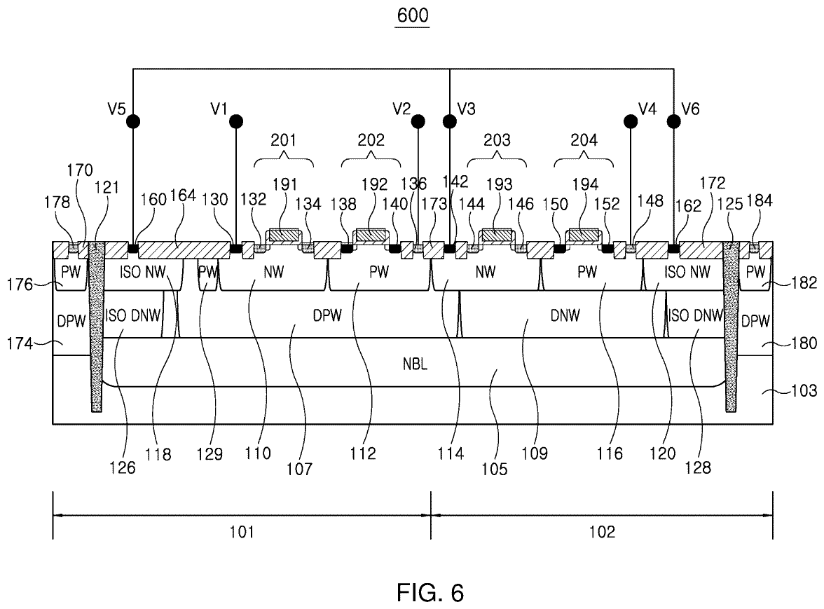

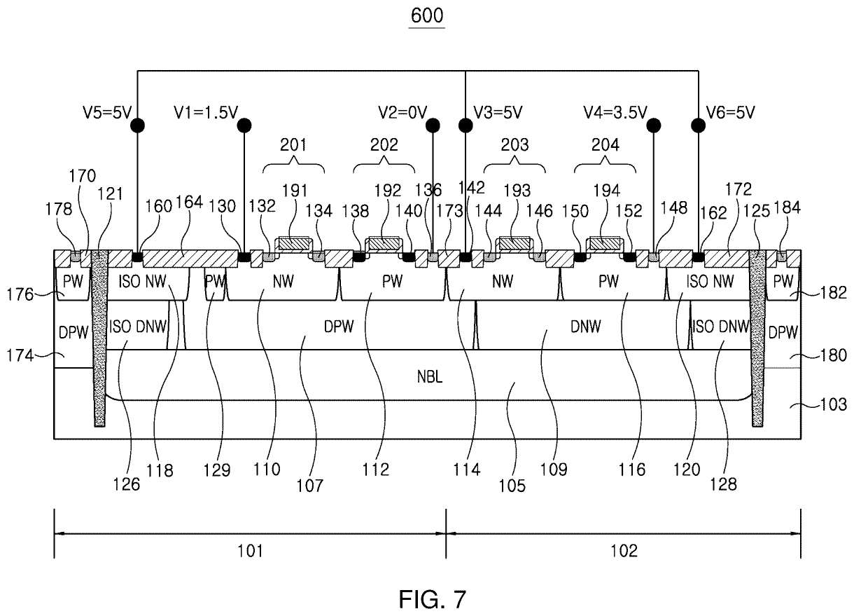

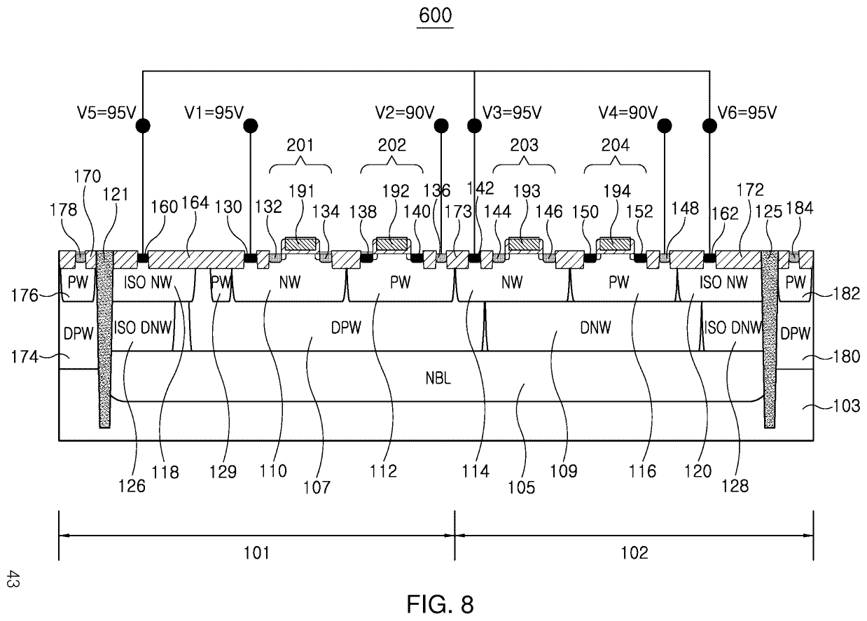

FIG. 6, FIG. 7 and FIG. 8 illustrate cross-sectional views of a semiconductor device isolation for multi-body bias according to an example of the present disclosure.

Referring first to FIG. 6, a semiconductor device 600 according to an example of the present disclosure includes: a semiconductor substrate 103 including a first region 101 and a second region 102; an n-type buried layer (NBL) 105 formed across the first region 101 and the second region 102; a P-type deep well region (DPW) 107 and an N-type deep well region (DNW) 109 formed on the NBL 105 and arranged side by side; a first NW 110 and a first PW 112 formed on the DPW 107 in the first region 101 and adjacent to each other; a second NW 114 and a second PW 116 formed on the DNW 109 in the second region 102 and adjacent to each other; a first PMOS device 201 and a first NMOS device 202 formed in the first region 101, in the first NW 110 and the first PW 112, respectively; a second PMOS device 203 and a second NMOS device 204 formed in the second region 102, in the second NW 114 and the second PW 116, respectively; a first ISO NW 118 formed in the first region 101 adjacent to the first PMOS device 201 and electrically isolated from the first NW 110 of the first PMOS device 201; a second ISO NW 120 formed in the second region 102 adjacent to the second NMOS device 204 and electrically connected to the second NW 114 of the second PMOS device 203; a first DTI 121 formed adjacent to the first ISO NW 118 and extending deeper than the NBL 105; and a second DTI 125 formed adjacent to the second ISO NW 120 and extending deeper than the NBL 105. An additional PW 129 may further be formed between the first NW 110 and the first ISO NW 118 to enhance breakdown voltage. The additional PW 129 may be formed within the DPW 107. The substrate 103 may be a P-type doped substrate.

Referring to FIG. 6, the semiconductor device 600 may further include: a first ISO DNW 126 connecting the NBL 105 and the first ISO NW 118, and a second ISO DNW 128 connecting the NBL 105 and the second ISO NW 120. The first ISO DNW 126 and the second ISO DNW 128 may be formed adjacent to the DPW 107 and the DNW 109, respectively. The bottom surfaces of the DPW 107, the DNW 109, the first ISO DNW 126, and the second ISO DNW 128 may all be in contact with the top surface of the n-type buried layer NBL 105.

In the semiconductor device 600, the first PMOS device 201 in the first region 101 may include: a first N-type high concentration (N+) body region 130 formed in the first NW 110; a first P-type high concentration (P+) source region 132; a first P+ drain region 134; and a first gate electrode 191. The first NMOS device 202 in the first region 101 may include: a first P+ body region 136; a first N+ source region 138; a first N+ drain region 140; and a second gate electrode 192, all of which are formed in the first PW 112.

Similarly, the second PMOS device 203 in the second region 102 may include: a second N+ body region 142; a second P+ source region 144; a second P+ drain region 146; and a third gate electrode 193, all of which are formed in the second NW 114. The second NMOS device 204 in the second region 102 may include: a second P+ body region 148 formed in the second PW 116; a second N+ source region 150; and a second N+ drain region 152.

Referring to FIG. 6, the semiconductor device 600 may further include a first node V1 connected to the first NW 110 of the first PMOS device 201, and a second node V2 connected to the first PW 112 of the first NMOS device 202. The first node V1 and the second node V2 are connected to the first NW 110 and the first PW 112, respectively. The first node V1 and the second node V2 are connected to well regions of different conductivity types. A self-body bias may electrically apply to each of the first node V1 and the second node V2 (see FIGS. 7 and 8). Applying the self-body bias may effectively create a voltage difference between the first node V1 and the second node V2, which allows for dynamic adjustment of the first PMOS and NMOS transistor's (201 and 202) threshold voltage, impacting its switching behavior and performance, to optimize power consumption and circuit characteristics.

Additionally, the first NW 110 and the first PW 112, which are respectively connected to the first node V1 and the second node V2, are electrically isolated from the substrate 103 by the NBL 105 and the DPW 107. Therefore, the first node V1 and the second node V2 may apply voltages different from that of the substrate 103.

The semiconductor device 600 may further include a third node V3 connected to the second NW 114 of the second PMOS device 203, and a fourth node V4 connected to the second PW 116 of the second NMOS device 204. A self-body bias may electrically apply to each of the third node V3 and the fourth node V4 (see FIGS. 7 and 8). Applying self-body bias may effectively create a voltage difference between the third node V3 and the fourth node V4, which allows for dynamic adjustment of the second PMOS and NMOS transistor's (203 and 204) threshold voltage, impacting its switching behavior and performance, to optimize power consumption and circuit characteristics.

Referring to FIG. 6, each of the first node V1 and the third node V3 which are electrically connected to the first NW 110 and the second NW 114, respectively, may apply self-body bias. This is because the first NW 110 connected to the first node V1 is surrounded by a P-type well region including the DPW 107, the first PW 112, and the additional PW 129. The P-type well region including the DPW 107, the first PW 112, and the additional PW 129 prevents an electrical short between the first NW 110 and the second NW 114. As a result, the chip size may be reduced. In conventional methods, it was necessary to form at least two or more deep trench isolations (DTIs) to prevent an electrical short between the first NW 110 and the second NW 114. Without the need to form two or more DTIs, this structure effectively prevents an electrical short between the two NWs 110 and 114.

Similarly, each of the second node V2 and the fourth node V4 which are connected to the first PW 112 and the second PW 116, respectively, may apply self-body bias. This is because the second PW 116 connected to the fourth node V4 is surrounded by an N-type well region including the DNW 109, the second NW 114, and the second ISO NW 120. The N-type well region comprising the DNW 109, the second NW 114, and the second ISO NW 120 prevents an electrical short between the first PW 112 and the second PW 116. As a result, the chip size may be reduced. In conventional methods, it was necessary to form at least two or more deep trench isolations (DTIs) to prevent an electrical short between the first PW 112 and the second PW 116. Without the need to form two or more DTIs, this structure effectively prevents an electrical short between the two PWs 112 and 116.

The semiconductor device 600 further comprises a fifth node V5 connected to the first ISO NW 118; and a sixth node V6 connected to the second ISO NW 120. The third node V3, the fifth node V5, and the sixth node V6 are electrically coupled, enabling the application of the same voltage to all three nodes. Consequently, it is possible to apply the same voltage, such that V3=V5=V6=5V. The third node V3, the fifth node V5, and the sixth node V6 are electrically coupled because they are all linked through regions of the same conductivity type, N-type, including the NBL 105, DNW 109, second NW 114, first ISO DNW 126, second ISO DNW 128, first ISO NW 118, and second ISO NW 120.

Referring to FIG. 6, in the semiconductor device 600, the first PMOS device 201, the first NMOS device 202, the second PMOS device 203, and the second NMOS device 204 are sequentially disposed side by side. The DPW 107 and the DNW 109, which are formed alongside each other, electrically isolate the first PMOS device 201 from the second PMOS device 203, and electrically isolate the first NMOS device 202 from the second NMOS device 204.

In the semiconductor device 600, the first NW 110 of the first PMOS device 201 may be electrically isolated from the second NW 114 of the second PMOS device 203. Additionally, the first PW 112 of the first NMOS device 202 may be electrically isolated from the second PW 116 of the second NMOS device 204.

The DPW 107 is formed in contact with the bottom surfaces of the first NW 110, the first PW 112, and the second NW 114 in the semiconductor device 600. Similarly, the DNW 109 may be formed in contact with the bottom surfaces of the second PW 116 and the second NW 114.

In the semiconductor device 600, the first PMOS 201 is surrounded by the DPW 107 and the first PW 112. The first NMOS 202 is surrounded by the DPW 107, the first NW 110, and the second NW 114. Additionally, the first NMOS 202 is surrounded by the first PMOS 201 and the second PMOS 203. The second PMOS 203 is surrounded by the DPW 107, the DNW 109, the first PW 112, and the second PW 116. The second NMOS 204 is surrounded by the DNW 109, the second NW 114, and the second ISO NW 120.

The semiconductor device 600 may further include a first shallow trench isolation 170 formed to overlap the first DTI 121; a second shallow trench isolation 172 formed to overlap the second DTI 125; a first isolation deep P-type well region (ISO DPW) 174 formed below the first STI 170 and electrically connected to the substrate 103; a first isolation P-type well region (ISO PW) 176; and a first isolation P+ region (ISO P+) 178.

The semiconductor device 600 may further include a second ISO DPW 180 formed below the second STI 172 and electrically connected to the substrate 103; a second ISO PW 182; and a second ISO P+ 184.

Referring to FIG. 7, it may be observed that different multiple voltages are applied to each well region. In the semiconductor device 600 of the present disclosure, the first NW 110, the first PW 112, the second NW 114, the second PW 116, the first ISO NW 118, and the second ISO NW 120 are connected to V1, V2, V3, V4, V5, and V6, respectively. The voltages may be applied as follows: V1=1.5V, V2=0V, V3=5V, V4=3.5V, and V5=V6=5V. V1 to V4 allow for the application of different body biases, and the same voltage may be applied such that V3=V5=V6=5V.

Referring to FIG. 7, a self-body bias may be electrically applied to each of the first node V1, the second node V2, the third node V3 and the four node V4. Applying the self-body bias may effectively generate a voltage difference from V1 to V4, which can dynamically adjust the threshold voltage of the first and second PMOS and NMOS transistors (201 to 204), thereby affecting switching behavior and performance, and optimizing power consumption and circuit characteristics.

Referring to FIG. 7, in the semiconductor device 600 of the present disclosure, V1 is applied at a higher voltage than V2. In other words, 1.5V may be applied to the first NW 110, and 0V may be applied to the first PW 112. It is preferable to apply a higher voltage to the first NW 110 than to the first PW 112. This is because if a higher voltage is applied to the first PW 112, a PN diode operation may occur between the first PW 112 and the first NW 110. When such a PN diode operation occurs, leakage current may easily flow from the first PW 112 to the first NW 110. To avoid this PN diode operation, it is preferable to apply a higher voltage to the first NW 110 than to the adjacent first PW 112.

Referring to FIG. 7, a higher voltage may be applied to V3 than to V4. In other words, 5.0V may be applied to the second NW 114, and 3.5V may be applied to the second PW 116. As previously described, it is preferable to apply a higher voltage to the second NW 114 than to the second PW 116. This is because if a higher voltage is applied to the second PW 116, a PN diode operation may occur between the second PW 116 and the second NW 114. When such a PN diode operation occurs, leakage current may easily flow from the second PW 116 to the second NW 114. To avoid this PN diode operation, it is desirable to apply a higher voltage to the second NW 114 than to the second PW 116 which is adjacent to it.

As explained in the previous examples, different voltages may be applied to V1 and V3, such as V1=1.5V, V2=0V, V3=5V, V4=3.5V. As shown, V1=1.5V and V3=5V may each be applied as distinct voltages. Specifically, V1 and V3 are electrically connected to the first NW 110 and the second NW 114, respectively, allowing different voltages to be applied to the first NW 110 and the second NW 114. This is made possible because the first NW 110 and the second NW 114 are electrically isolated from each other by the DPW 107 and the DNW 109.

Additionally, V2 and V4 are electrically connected to the first PW 112 and the second PW 116, respectively, allowing different voltages to be applied to the first PW 112 and the second PW 116, i.e., V2=0V and V4=3.5V may be applied. This is made possible because the first PW 112 and the second PW 116 are electrically isolated from each other by the DPW 107 and the DNW 109.

Referring to FIG. 8, different multiple voltages may be applied to each well region. In the semiconductor device 600 of the present disclosure, the first NW 110, the first PW 112, the second NW 114, the second PW 116, the first ISO NW 118, and the second ISO NW 120 are connected to V1, V2, V3, V4, V5, and V6, respectively. Due to the breakdown voltage difference of 5V or less between the NWs 110, 114 and the PWs 112, 116, it is possible to apply a voltage higher than the PWs to the NWs, provided the voltage difference does not exceed 5V. For example, if V1=95V is applied to the first NW 110, V2 connected to the first PW 112 may be set between 90V and 95V. Similarly, if V3=95V is applied to the second NW 114, V4 connected to the second PW 116 may be set between 90V and 95V. Additionally, V5 and V6 may both be set to 95V. Since V5 and V6 are electrically connected to V3, the same voltage may be applied, making V3=V5=V6=95V. Furthermore, V1 to V4 may be independently biased, allowing for different body biases to be applied to these regions.

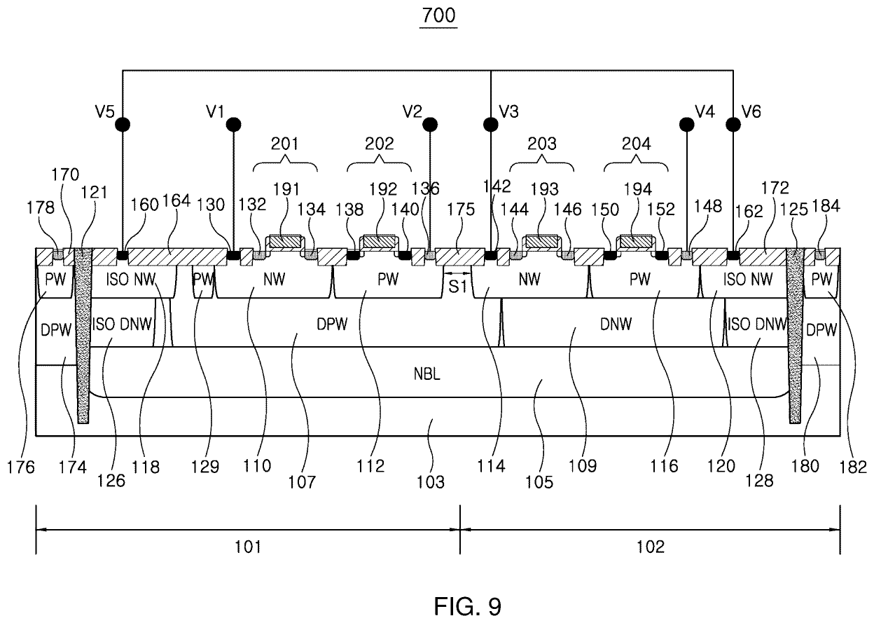

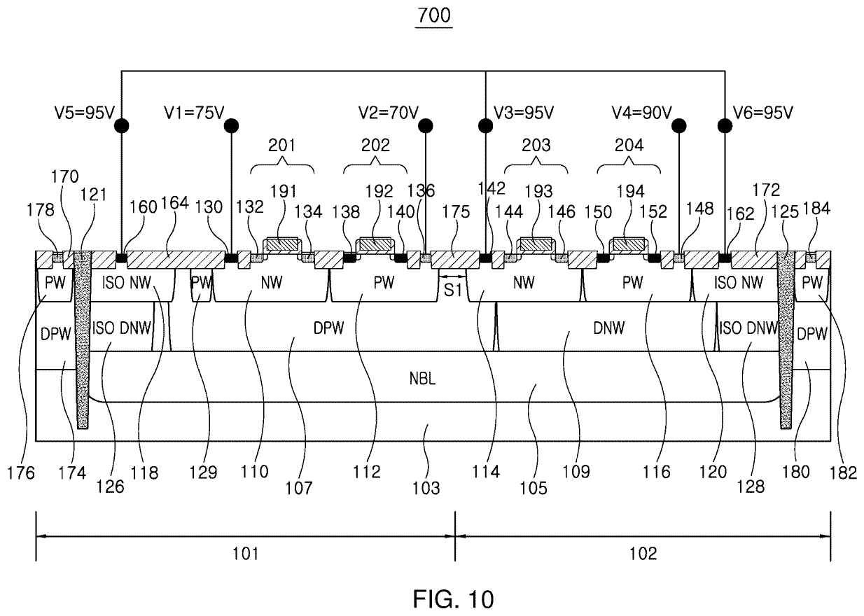

FIG. 9 and FIG. 10 illustrate cross-sectional views of a semiconductor device isolation for multi-body bias according to another example of the present disclosure.

Referring FIG. 9, FIG. 9 is similar to FIG. 6. However, in a semiconductor device 700, the width of a third shallow trench isolation 175 is formed longer than the width of a third shallow trench isolation 173 shown in the semiconductor device 600 in FIG. 6 or FIG. 7. When the width of the third shallow trench isolation 175 is extended in this manner, a spacing S1 between a first PW 112 and a second NW 114 may increase accordingly. As a result, the breakdown voltage between the first PW 112 and the second NW 114 may increase significantly. For example, in FIG. 7, the first PW 112 and the second NW 114 are formed in contact with each other, and in this case, the breakdown voltage between the first PW 112 and the second NW 114 is approximately 5V. This means that the voltage difference between V2 and V3 may only be within 5V. However, when the spacing S1 between the first PW 112 connected to V2 and the second NW 114 connected to V3 is increased to 1.5 μm or more, the breakdown voltage between the first PW 112 and the second NW 114 may increase to 20V or more. This means that the voltage difference between V2 and V3 may exceed 20V.

Referring to FIG. 10, it may be observed that different multiple voltages are applied to each well region. In a semiconductor device 700, because the breakdown voltage difference between a first NW 110 and a first PW 112, which are in contact with each other, is within 5V, it is possible to apply a voltage higher than the first PW 112 to the first NW 110, as long as the voltage difference is within 5V. For example, when V1=75V is applied to the first NW 110, V2 connected to the first PW 112 may range from 70V to 75V (the difference between V1 and V2 is within 5V). Similarly, when V3=95V is applied to a second NW 114, V4 connected to a second PW 116 may range from 90V to 95V (the difference between V3 and V4 is within 5V). Furthermore, V3 is electrically connected to V5 and V6, allowing the same voltage to be applied, resulting in V3=V5=V6=95V. In this manner, a very high voltage in the range of 90V to 95V may be applied to the semiconductor device 700.

Referring to FIG. 10, in the semiconductor device 700, when a spacing S1 between the first PW 112 connected to V2 and the second NW 114 connected to V3 is 1.5 μm or greater, the breakdown voltage may increase to 20V or more. Consequently, when V2=70V is applied to the first PW 112, V3 connected to a second NW 114 may be applied within a range of 70V to 95V. This demonstrates that a very wide range of high voltage may be applied to the semiconductor device 700.

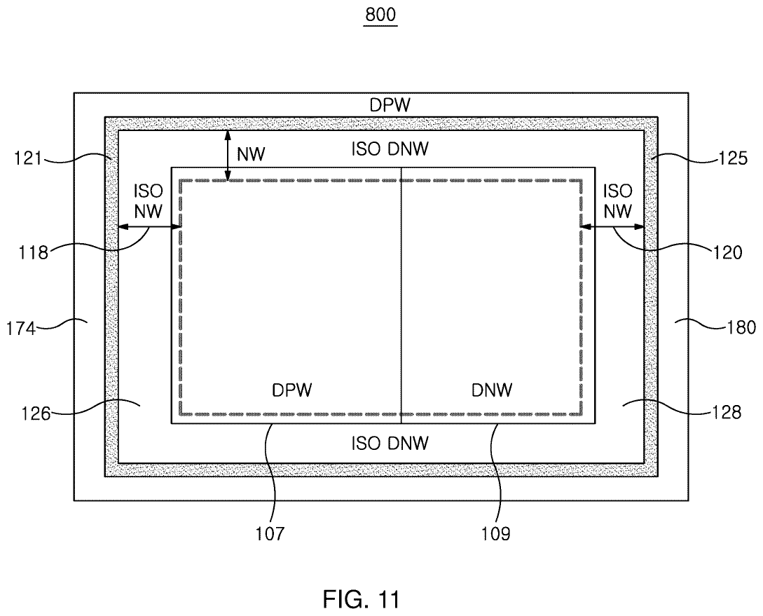

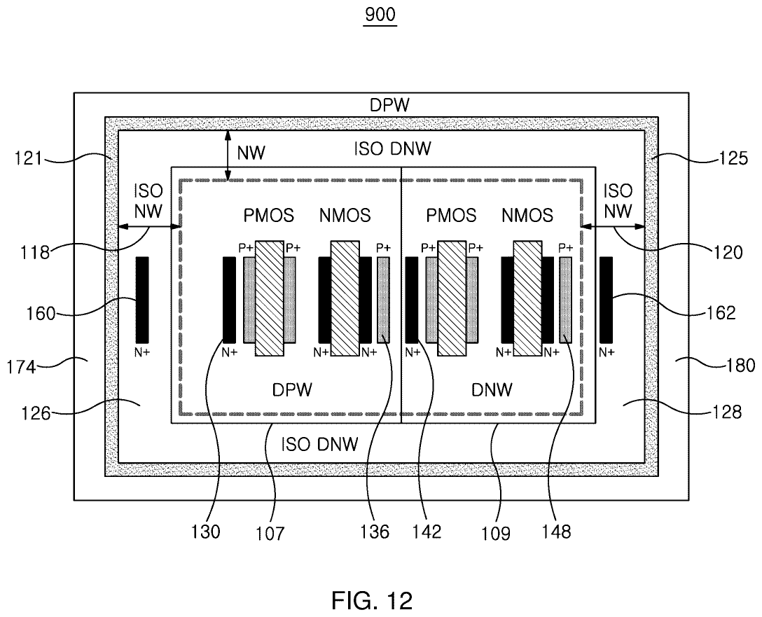

FIG. 11 and FIG. 12 illustrate plan views of a semiconductor device isolation for multi-body bias according to another embodiment of the present disclosure.

Referring to FIG. 11, a DPW 107 and a DNW 109 may be formed in contact with each other in a semiconductor device 800. Additionally, isolation deep N-type well regions (ISO DNW) 126, 128 may be formed to surround the DPW 107 and the DPW 116 in the semiconductor device 800. ISO NWs 118, 120 may be formed to overlap with the ISO DNW 126, 128. The ISO NWs 118, 120 may also be formed to overlap with the DPW 107 and the DNW 109. Referring to FIGS. 1 to 5, the ISO DNW 126, 128 and the ISO NWs 118, 120 are electrically connected to an NBL 105. Furthermore, deep trench isolation (DTI) 121, 125 may be formed in the substrate to surround the ISO DNW 126, 128. ISO DPW 174, 180 may then be formed to surround the DTI 121, 125.

Referring to FIG. 12, a first PMOS 201 and a first NMOS 202 may be formed on a DPW 107 in a semiconductor device 900. Additionally, a second PMOS 203 and a second NMOS 204 are formed on a DNW 109 in the semiconductor device 900. Furthermore, N+ region 130 and P+ region 136 are formed on the DPW 107 to apply V1 and V2 voltages, respectively. As described earlier, the V1 and V2 voltages are different from each other.

Similarly, N+ region 142 and P+ region 148 are formed on the DNW 109 to apply V3 and V4 voltages, respectively. As described earlier, the V3 and V4 voltages are different from each other. Moreover, V1 to V4 may each be set to different voltages.

Additionally, N+ regions 160, 162 may be formed to apply voltage to an NBL 105, first and second ISO DNW 126, 128, and first and second ISO NWs 118, 120.

In the semiconductor device 900, the DPW 107 may be formed to overlap with a first PMOS 201 and a first NMOS 202. Similarly, the DNW 109 may be formed to overlap with a second PMOS 203 and a second NMOS 204.

According to the present disclosure, a semiconductor device with a compact isolation structure and multi-body bias capability may be provided. The present disclosure also provides a structure for a semiconductor device having a compact structure and multiple body bias.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A semiconductor device, comprising:
an N-type buried layer (NBL) formed on a semiconductor substrate;
an N-type deep well region (DNW) or a P-type deep-well region (DPW) formed on the NBL;
a deep trench structure including a first deep trench isolation (first DTI) and a second deep trench isolation (second DTI) surrounding the NBL;
a first isolation N-type well region (first ISO NW) and a second isolation N-type well region (second ISO NW) formed on the NBL;
a first ISO N-type high-concentration region (first ISO N+ region) and a second ISO N-type high-concentration region (second ISO N+ region) formed on the first ISO NW and the second ISO NW, respectively;
a first N-type well region (first NW) and a first P-type well region (first PW) formed between the first ISO NW and the second ISO NW;
a first PMOS device including a first gate electrode formed on the first NW, a first N-type high-concentration body region (first N+ body region), a first P-type high-concentration source region (first P+ source region), and a first P-type high-concentration drain region (first P+ drain region);
a first NMOS device including a second gate electrode formed on the first PW, a first P-type high-concentration body region (first P+ body region), a first N-type high-concentration source region (first N+ source region), and a first N-type high-concentration drain region (first N+ drain region); and
a field stop PW formed between the first NW and the first ISO NW,
wherein the first DTI is formed in contact with the NBL and the first ISO NW and is formed deeper than the NBL, and
wherein the second DTI is formed in contact with the NBL and the second ISO NW and is formed deeper than the NBL.

2. The semiconductor device of claim 1, further comprising:
an isolation node electrically connected in common with the first ISO NW and the second ISO NW;
a first node electrically connected to the first NW of the first PMOS device; and
a second node electrically connected to the first PW of the first NMOS device,
wherein the isolation node, the first node, and the second node apply an isolation voltage, a first voltage, and a second voltage, respectively,
wherein the first node and the isolation node are electrically connected to each other and apply the same voltage to each other, and
wherein the second node applies the second voltage that is lower than the first voltage.

3. The semiconductor device of claim 2, wherein a self-body bias is electrically applied to each of the first node and the second node.

4. The semiconductor device of claim 1, wherein the first PMOS device and the first NMOS device are surrounded by the first DTI, the second DTI, the first ISO NW and the second ISO NW.

5. The semiconductor device of claim 1, further comprising:
a first isolation N-type deep-well region (first ISO DNW) formed between the NBL and the first ISO NW;
a second isolation N-type deep-well region (second ISO DNW) formed between the NBL and the second ISO NW;
a first isolation deep P-type well region (first ISO DPW) and a first isolation P-type well region (first ISO PW) formed adjacent to the first DTI and electrically connected to the substrate; and
a second isolation deep P-type well region (second ISO DPW) and a second isolation P-type well region (second ISO PW) formed adjacent to the second DTI and electrically connected to the substrate.

6. A semiconductor device, comprising:
a first deep trench isolation (first DTI), a second deep trench isolation (second DTI), a third deep trench isolation (third DTI) and a fourth deep trench isolation (fourth DTI) formed in a semiconductor substrate, wherein the first DTI and the fourth DTI are connected to each other, and the second DTI and the third DTI are connected to each other;
a first region disposed between the first DTI and the second DTI;
a second region disposed between the second DTI and the third DTI;
an ISO region disposed between the third DTI and the fourth DTI;
a first N-type buried layer (first NBL), a second N-type buried layer (second NBL), and a third N-type buried layer (third NBL) formed in the first region, the second region, and the ISO region, respectively;
a first isolation N-type deep well region (first ISO DNW) and a P-type deep well region (DPW) formed on the first NBL;
an N-type deep well region (DNW) formed on the second NBL;
a second isolation N-type deep well region (second ISO DNW) formed on the third NBL;
a first isolation N-type well region (first ISO NW) formed on the first ISO DNW;
a first N-type well region (first NW) and a first P-type well region (first PW) formed on the DPW and formed in contact with each other;
a second N-type well region (second NW) and a second P-type well region (second PW) formed on the DNW and formed in contact with each other;
a second isolation N-type well region (second ISO NW) formed on the second ISO DNW;
a first PMOS device and a first NMOS device formed in the first region and each formed on the first NW and the first PW, respectively; and
a second PMOS device and a second NMOS device formed in the second region and each formed on the second NW and the second PW,
wherein the first DTI is formed in contact with the first NBL, the first ISO DNW, and the first ISO NW, and is formed deeper than the first NBL, and
wherein the fourth DTI is formed in contact with the third NBL, the second ISO DNW, and the second ISO NW, and is formed deeper than the third NBL.

7. The semiconductor device of claim 6,
wherein the first PMOS device includes a first N-type high-concentration body region (first N+ body region), a first P-type high-concentration source region (first P+ source region), and a first P+ drain region formed in the first NW,
wherein the first NMOS device includes a first P+ body region, a first N+ source region, and a first N+ drain region formed in the first PW,
wherein the second PMOS device includes a second N+ body region, a second P+ source region, and a second P+ drain region formed in the second NW, and
wherein the second NMOS device includes a second P+ body region, a second N+ source region, and a second N+ drain region formed in the second PW.

8. The semiconductor device of claim 6, further comprising:
an isolation node electrically connected to the first ISO NW and the second ISO NW;
a first node electrically connected to the first NW of the first PMOS device;
a second node electrically connected to the first PW of the first NMOS device;
a third node electrically connected to the second NW of the second PMOS device; and
a fourth node electrically connected to the second PW of the second NMOS device,
wherein the isolation node, the first node, the second node, the third node and the fourth node apply an isolation voltage, a first voltage, a second voltage, a third voltage and a fourth voltage, respectively, such that a self-body bias is electrically applied to each of the first node, the second node, the third node and the fourth node,
wherein the isolation node and the third node are electrically isolated from each other,
wherein the second node applies the second voltage which is lower than the first voltage, and
wherein the fourth node applies the fourth voltage that is lower than the third voltage.

9. The semiconductor device of claim 6,
wherein the first PMOS device, the first NMOS device, the second PMOS device, and the second NMOS device are disposed in that order,
wherein the DPW is formed in contact with a bottom surface of the first NW and the first PW, and
wherein the DNW is in contact with a bottom surface of the second PW and the second NW.

10. The semiconductor device of claim 6,
wherein a first deep trench structure comprises the first DTI and the fourth DTI connected to each other,
wherein a second deep trench structure comprises the second DTI and the third DTI connected to each other, and
wherein the first deep trench structure is configured to surround the second deep trench structure.

11. A semiconductor device, comprising:
a semiconductor substrate comprising a first region and a second region;
an N-type buried layer (NBL) formed across the first region and the second region;
a P-type deep well region (DPW) and an N-type deep well region (DNW) formed on the NBL and disposed adjacent to each other;
a first n-type well region (first NW) and a first p-type well region (first PW) formed on the DPW in the first region and disposed in contact with each other;
a second n-type well region (second NW) and a second p-type well region (second PW) formed on the DNW in the second region and disposed in contact with each other;
a first PMOS device and a first NMOS device formed in the first region, wherein the first PMOS device is formed on the first NW, and the first NMOS device is formed on the first PW;
a second PMOS device and a second NMOS device formed in the second region, wherein the second PMOS device is formed on the second NW, and the second NMOS device is formed on the second PW;
a first isolation N-type well region (first ISO NW) formed in the first region adjacent to the first PMOS device and electrically isolated from the first NW of the first PMOS device;
a second isolation N-type well region (second ISO NW) formed in the second region adjacent to the second NMOS device and electrically connected to the second NW of the second PMOS device;
a first deep trench isolation (first DTI) formed adjacent to the first ISO NW and extending deeper than the NBL; and
a second deep trench isolation (second DTI) formed adjacent to the second ISO NW and extending deeper than the NBL.

12. The semiconductor device of claim 11, further comprising:
a first isolation deep N-type well region (first ISO DNW) configured to connect the NBL and the first ISO NW; and
a second isolation deep N-type well region (second ISO DNW) configured to connect the NBL and the second ISO NW.

13. The semiconductor device of claim 11,
wherein the first PMOS device comprises a first N-type high concentration body region (first N+ body region) formed in the first NW, a first P-type high concentration source region (first P+source region), and a first P+ drain region,
wherein the first NMOS device comprises a first P+ body region formed in the first PW, a first N+ source region, and a first N+ drain region,
wherein the second PMOS device comprises a second N+ body region formed in the second NW, a second P+ source region, and a second P+ drain region, and
wherein the second NMOS device comprises a second P+ body region formed in the second PW, a second N+ source region, and a second N+ drain region.

14. The semiconductor device of claim 11, further comprising:
a first node connected to the first NW of the first PMOS device;
a second node connected to the first PW of the first NMOS device;
a third node connected to the second NW of the second PMOS device;
a fourth node connected to the second PW of the second NMOS device;
a fifth node connected to the first ISO NW; and
a sixth node connected to the second ISO NW,
wherein a self-body bias is electrically applied to each of the first node, the second node, the third node and the fourth node, and
wherein the third node, the fifth node, and the sixth node are electrically coupled together and configured to receive a same voltage.

15. The semiconductor device of claim 11,
wherein the first PMOS device, the first NMOS device, the second PMOS device, and the second NMOS device are disposed in sequence side by side,
wherein the first PMOS device is surrounded by the DPW, and the first NMOS device is electrically isolated from the second PMOS device,
wherein the first NMOS device is surrounded by the first PMOS device, the second PMOS device, and the DPW to be electrically isolated from the second NMOS device,
wherein the second PMOS device is surrounded by the first PMOS device, the second NMOS device, and the DNW to be electrically isolated from the first PMOS device,
wherein the second NMOS device is surrounded by the second PMOS device, the DNW, and the second ISO NW to be electrically isolated from the first NMOS device,
wherein the DPW is formed below the first PMOS device and the first NMOS device to overlap the first PMOS device and the first NMOS device, and
wherein the DNW is formed below the second PMOS device and the second NMOS device to overlap the second PMOS device and the second NMOS device.

16. The semiconductor device of claim 11, further comprising:
a first shallow trench isolation (first STI) formed to overlap the first DTI;
a second shallow trench isolation (second STI) formed to overlap the second DTI;
a first isolation deep P-type well region (first ISO DPW) and a first isolation P-type well region (first ISO PW) formed below the first STI and electrically connected to the substrate; and
a second isolation deep P-type well region (second ISO DPW) and a second isolation P-type well region (second ISO PW) formed below the second STI and electrically connected to the substrate.
